(19) United States
(12) Patent Application Publication
(10) Pub. No.: US 2012/0139047 A1
(43) Pub. Date: Jun. 7, 2012

(54) SEMICONDUCTOR DEVICE AND METHOD OF MANUFACTURING THE SAME

(76) Inventors: Jun Luo, Beijing (CN); Chao Zhao, Kessel-lo (BE)

(21) Appl. No.: 13/380,096

(22) PCT Filed: Feb. 27, 2011
(86) PCT No.: PCT/CN11/71356

§ 371 Date: Dec. 22, 2011

(30) Foreign Application Priority Data
Nov. 29, 2010 (CN) 201010571659.4

(51) Int. Cl. H01L 29/78; H01L 21/336

(52) U.S. Cl. 257/347; 257/288; 438/303; 438/151; 257/E29.255; 257/E21.409

(57) ABSTRACT

Disclosed is a semiconductor device, comprising a substrate, a channel region in the substrate, source/drain regions on both sides of the channel region, a gate structure on the channel region, and gate sidewall spacers formed on the sidewalls of the gate structure, characterized in that each of the source/drain regions comprises an epitaxially grown metal silicide region, and dopant segregation regions are formed at the interfaces between the epitaxially grown metal silicide source/drain regions and the channel region. By employing the semiconductor device and the method for manufacturing the same according to embodiments of the present invention, the Schottkey Barrier Height of the MOSFETs with epitaxially grown ultrathin metal silicide source/drain may be lowered, thereby improving the driving capability.

### TECHNICAL FIELD

The present application relates to a semiconductor device, and more specifically, relates to a MOSFET structure that has epitaxially grown ultra-thin metal silicide source/drain and a method for manufacturing the same.

### BACKGROUND OF THE INVENTION

In the current IT application field, with the increasing demand on the IC integration level and continuous proportional scaling of the traditional MOSFET, some parameters that are controllable through processing, such as channel length, gate oxide layer thickness, substrate doping concentration, etc., may be scaled proportionally. Although scaling the device size results in a greater process fluctuation, many physical parameters, such as the silicon forbidden band, the Fermi potential, interface states, oxide layer charges, thermoelectric potentials, and p-n junction built-in potentials, cannot be scaled proportionally. These will greatly deteriorate the performance of proportionally scaled device.

One problem resulting in deterioration is the source/drain series resistance. When the channel resistance is greater than the source/drain region series resistance, the impact of parasitic series resistance may be neglected. However, the source/drain resistance is not proportionally scaled with the scaling of size. In particular, the contact resistance increases approximately in an inverse square relationship with the scaling down of the size, which causes drops of equivalent operating voltages. If the traditional highly doped source/drain in the existing MOSFET manufacturing technology is replaced with the metal silicide source/drain, the parasitic series resistance and contact resistance may be reduced to a great extent.

As illustrated in FIG. 1, it illustrates a diagram of an existing metal silicide source/drain MOSFET (also called Schottky Barrier source/drain MOSFET). Metal silicide source/drain regions 30 and 31 are respectively formed on one side of the channel regions 20 and 21 in the body silicon substrate 10 or Silicon-On-Insulator (SOI) substrate 11. Gate structures 40/41 and gate sidewall spacers 50/51 are formed over the channel region in sequence. Metal silicide acts directly as a source/drain material that contacts the channel. In the device substrate, a shallow trench isolation STI 60/61 may be further formed. In the figures, STIs may be shown to be directly formed between a bulk silicon substrate and a SOI substrate, this is only for the sake of example and convenient comparison, the two substrates do not contact actually.

This metal silicide source/drain MOSFET has an optimum scalability feature and is easy to be manufactured. Thus, it has attracted tremendous attention and becomes one of the hot spots in the development of current MOSFET technology.

The driving capability of the metal silicide source/drain MOSFET is constrained by the Schottky Barrier Height (SBH) between its source and channel. With the decrease of SBH, the drive current increases. The result of device simulation shows that when the SBH decreases to about 0.1 eV, the metal silicide source/drain MOSFET may reach a driving capability comparable to the traditional MOSFET with highly doped source/drain.

FIG. 2 illustrates a way to decrease SBH using a silicide as diffusion source (SADS) method. First, dopants such as Boron and Arsenic are implanted into a silicide film 31. Next, annealing is performed at a temperature between 500 to 850° C. to make the dopants segregated at silicide/silicon interfaces, thereby forming dopant segregation regions 71 that are activated. The dopant segregation regions 71 lead to reduction of the SBH between the source and channel, thereby improving the driving capability of the device. Meanwhile, silicide film damage caused by ion implantation may also be repaired during the annealing.

With the gate length of metal silicide source/drain MOSFETs being reduced to a sub-20 nm level, the thickness of the metal silicide source/drain must be also reduced so as to control the short channel effects (SCEs), particularly with devices formed on SOI substrates.

In the metal silicide source/drain MOSFET as illustrated in FIG. 1, the channel regions 20/21 are relatively long, the metal silicide source/drain films 30/31 are relatively thick, which shows good thermal stability during annealing. However, with the reduction of the metal silicide source/drain thickness, its thermal stability will also be deteriorated. As illustrated in FIG. 3, when the dimensions are scaled down, the channels 20/21 are shortened, and the metal silicide source/drain films 30/31 must also be correspondingly thinned to better control the short channel effects. However, the thinned silicide films 30/31 inherently suffer from poor thermal stability during annealing, for example easy segregation, thus leading to drastically sheet resistance increase. For such thin silicide films 30/31, in the above-mentioned SADS method for decreasing the SBH, the silicide films cannot bear the high-temperature annealing required for inducing the dopants segregation at the silicide/silicon interface. As a result, the SBH cannot be decreased for the MOSFET with thin metal silicide source/drain.

Recently, metal silicide source/drain MOSFETs have been deemed as the structure for the next generation of sub-20 nm CMOS. However, in the sub-20 nm technology nodes, the existing SADS method to improve the driving capability through decreasing the SBH between the silicide source and the channel region cannot be implemented, because thin metallic silicide source/drain cannot bear the high-temperature annealing

Therefore, it is desirable to provide a method to effectively decrease the SBH for metal silicide source/drain MOSFETs in the sub-20 nm technology nodes and a metal silicide source/drain MOSFET thermally stable that is manufactured with the same method.

### SUMMARY OF THE INVENTION

In order to solve the above problem, the present invention provides a semiconductor device, comprising a substrate, a channel region in the substrate, source/drain regions on both sides of the channel region, a gate structure on the channel, and gate sidewall spacers formed on both sidewalls of the gate structure, characterized in that each of the source/drain regions is comprised of an epitaxially grown ultrathin metal silicide region, and a dopant segregation region is formed at the interface between each of the silicide source/drain regions and the channel.

In a preferred embodiment, the material of the epitaxially grown ultrathin metal silicide source/drain is one of NiSi_{2-y}, CoSi_{2-y}, and Ni₁₋ₓCoₓSi_{2-y}, where x is greater than 0 and less than 1, y is greater than and equal to 0 and less than 1. The thickness of the epitaxially grown ultrathin silicide source/drain is less than or equal to 15 nm. For p-type MOSFETs with epitaxially grown ultrathin metal silicide source/drain, the dopants are one or more of boron B, aluminum Al, gallium Ga, and indium In; for n-type MOSFETs with epitaxially grown ultrathin metal silicide source/drain, the dopants are one or more of nitrogen, phosphorus, arsenic, oxygen, sulphur, selenium, tellurium, fluorine, and chlorine. The substrate may be a bulk silicon substrate or a semiconductor-on-insulator (SOI) substrate.

The present invention further provides a method for manufacturing a semiconductor device, comprising:

forming a gate structure and gate sidewall spacers on a substrate;

depositing a metal layer covering the substrate, the gate structure, and the gate sidewall spacers;

performing a first annealing such that the metal layer on both sides of the gate reacts with the substrate to form epitaxially grown ultrathin metal silicide layers;

stripping unreacted portions of the metal layer, such that the epitaxially grown ultrathin metal silicide layers form source/drain regions of the device, and a channel region is formed in the portion of the semiconductor substrate beneath the gate structure;

implanting dopants into as-formed epitaxially grown ultrathin source/drain regions; and

performing a second annealing to form dopant segregation regions at the interfaces between the epitaxially grown ultrathin silicide source/drain and the channel region.

In a preferred embodiment, the epitaxially grown ultrathin metal silicide material is one of NiSi_{2-y}, Ni₁₋ₓPtₓSi_{2-y}, CoSi_{2-y}, and Ni₁₋ₓCoₓSi_{2-y}, where x is greater than 0 but less than 1, and y is greater or equal to 0 but less than 1.

The thickness of the epitaxially grown ultrathin silicide layers is less than or equal to 15 nm. For p-type MOSFETs with epitaxially grown ultrathin metal silicide source/drain, the dopants are one or more of boron B, aluminum Al, gallium Ga, and indium In; for n-type MOSFETs with epitaxially grown ultrathin metal silicide source/drain, the dopants are one or more of nitrogen, phosphorus, arsenic, oxygen, sulphur, selenium, tellurium, fluorine, and chlorine. The implantation dosage for implanted dopants ranges from 1×10¹⁴ to 1×10¹⁶ cm⁻².

In a preferred embodiment, the temperature for the first annealing and/or the second annealing is 500-850° C.

In a preferred embodiment, the thickness of deposited metal layers is less than or equal to 5 nm.

In a preferred embodiment, the substrate may be a bulk silicon substrate or a semiconductor-on-insulator (SOI) substrate.

These MOSFETs with epitaxially grown ultrathin metal silicide source/drain characterized by dopant segregation at the interfaces between silicide source/drain and channel region have many advantages. First, by replacing traditional highly doped source/drain with metal silicide source/drain, the ever-deteriorating problem of parasitic series resistance and contact resistance can be alleviated to a great extent, which can greatly improve the short channel effects immunity in the sub-20 nm CMOS technology nodes. Second, because the metal silicide precursor may be well controlled (namely, the thickness of the deposited metal layer and the processing parameters, particularly the time and the temperature range for the first annealing may be well controlled), the formed epitaxially grown ultrathin silicide film is made to have a better thermal stability and subjected to the silicide as diffusion source method to reduce the Schottky Barrier Height (SBH). Specifically, dopant segregation is formed at the silicide/silicon interface between each of the epitaxially grown ultrathin silicide source/drain and the channel region, thereby reducing the SBH and enhancing the driving capability of the device. Moreover, the second annealing under a high temperature for lowering the SBH may repair the damage of the silicide film caused by ion implantation. In short, by employing the MOSFET and the method for manufacturing the same according to embodiments of the present invention, MOSFETs with thermally stable epitaxially grown ultrathin metal silicide source/drain may be obtained in combination with the SADS method to reduce the SBH thus improving the driving capability of such devices.

The objectives as disclosed in the present invention and other objectives that are not specified here are achieved within the scope as defined by the independent claims of the present invention.

### BRIEF DESCRIPTION OF THE DRAWINGS

The technical solution of the present invention will be described in detail with reference to the accompanying drawings, wherein:

FIG. 1 is a cross-sectional diagram of an existing metal silicide source/drain MOSFET;

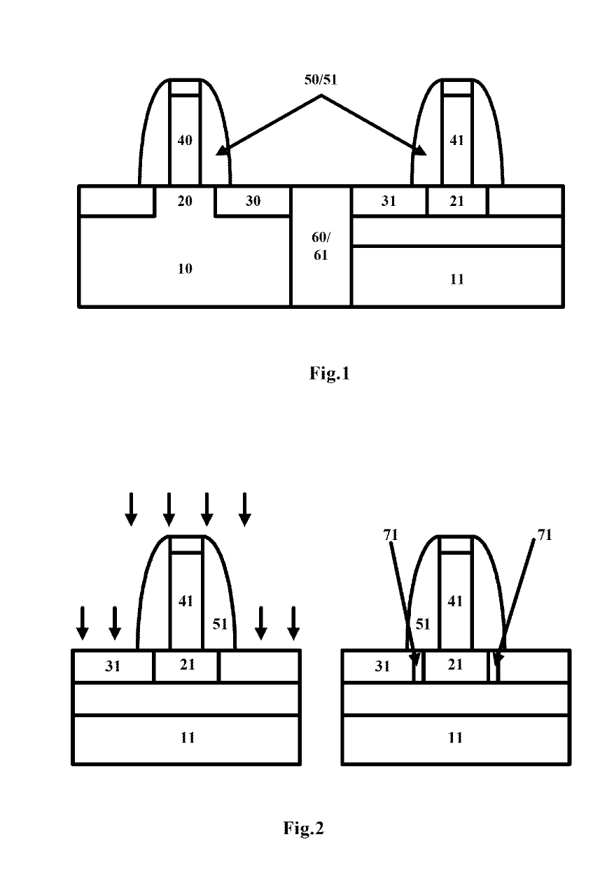

FIG. 2 is a diagram illustrating a method for lowering the SBH with the existing SADS technology;

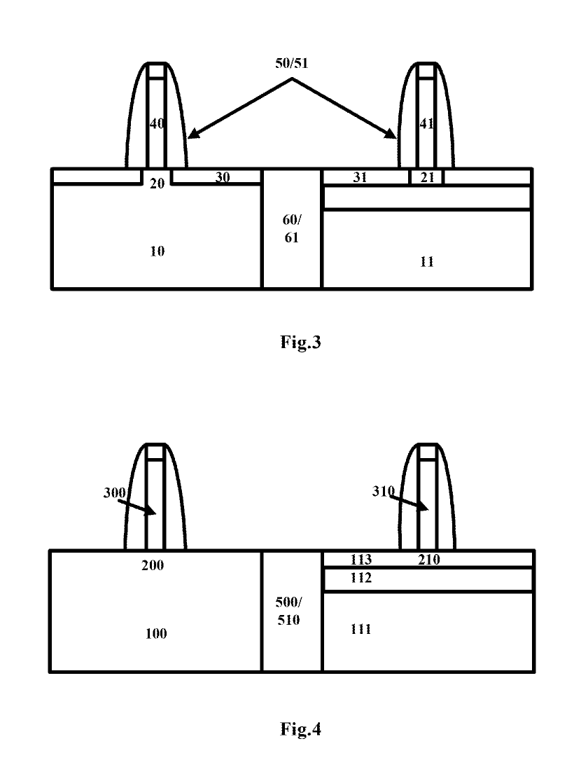

FIG. 3 is a cross-sectional diagram of a short-channel metal silicide source/drain MOSFET; and

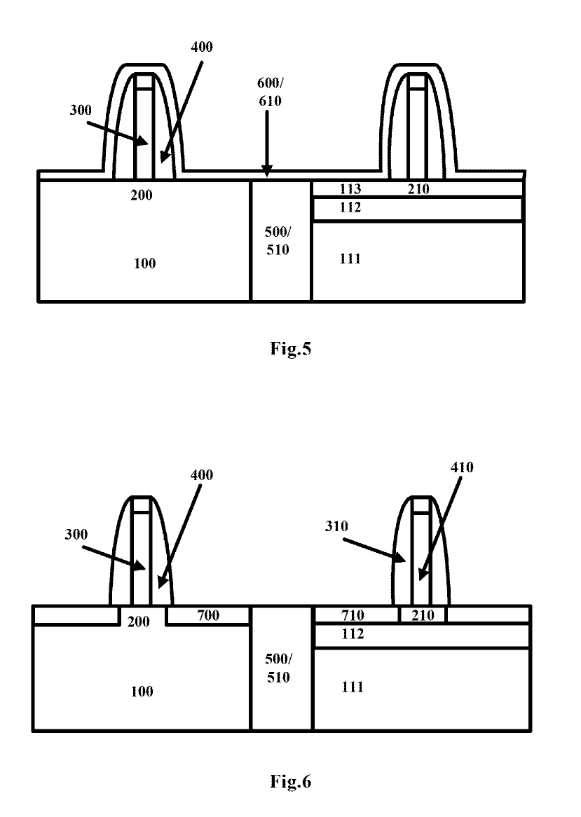

FIGS. 4 to 8 are cross-sectional diagrams of device structures corresponding to various steps of a method for manufacturing a MOSFET with epitaxially grown ultrathin metal silicide source/drain according to embodiments of the present invention.

### DETAILED DESCRIPTION OF THE PREFERRED EMBODIMENTS

Hereinafter, features and technical merits of various technical solutions of the present invention will be described in detail with reference to the drawings and in conjunction with illustrative embodiments. The present invention discloses a MOSFET with epitaxially grown ultrathin metal silicide source/drain that shows excellent thermal stability and a method for manufacturing the same. It should be noted that like numerals indicate like structures. In this application, the phrases “first,” “second,” “over,” and “beneath” may be used to modify various device structures. These modifications, otherwise specifically indicated, do not imply the spatial, sequential or hierarchical relationship of the modified device structure.

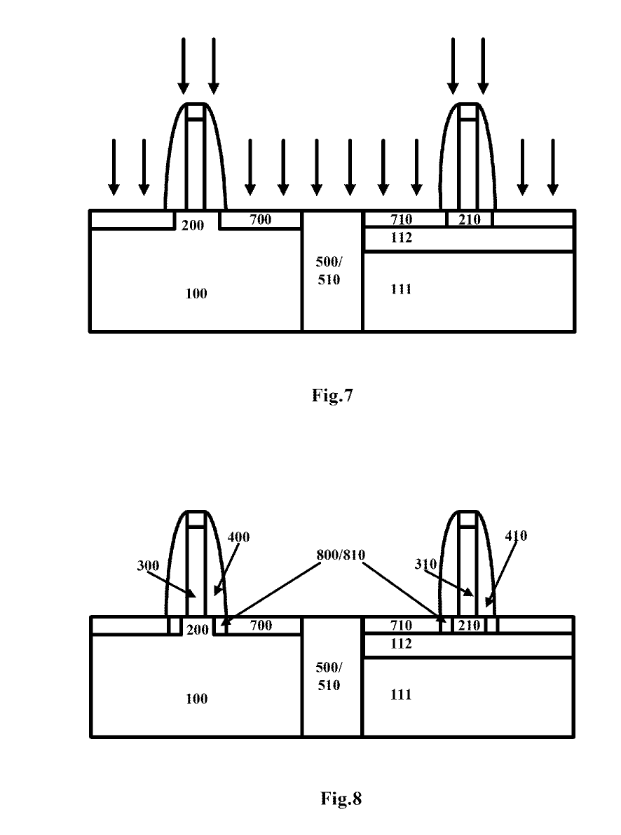

FIGS. 4-8 sequentially show cross-sectional views of device structures corresponding to the steps of a method for manufacturing a MOSFET with epitaxially grown ultrathin metal silicide source/drain in sequence. In these figures, the STIs are shown to be directly disposed between bulk-silicon substrates and SOI substrates, which are only for the sake of example and convenient comparison, the two substrates do not contact actually.

First, as illustrated in FIG. 4, a substrate is provided and a basic device structure has been formed thereon. In the embodiments of the present invention, a conventional bulk semiconductor substrate may be employed. The conventional bulk semiconductor substrate, for example, may comprise a bulk-silicon substrate or a bulk substrate of another basic semiconductor or compound semiconductor, for example, Ge, SiGe, GaAs, InP, or SiC, etc. Based on known design requirements (for example, p-type substrate or n-type substrate), the substrate 200 may comprise various doping configurations. It may comprise an epitaxial layer or even a semiconductor-on-insulator (SOI) structure, and it may have stress to enhance the performance. In the embodiments of the present invention, an SOI substrate is preferably used. Specifically, on the channel region 200 in the bulk-silicon substrate 100 or 210 in the silicon-on-insulator (SOI) substrate 110, a gate structure 300 or 310 is formed; on both sidewalls of the gate structure, gate sidewall spacers 400 or 410 are formed; the device substrate may be further arranged with a shallow trench isolation STI 500/510. In a preferred embodiment, the channel region 200/210 has a length less than or equal to 20 nm. In other words, the device is a sub-20 nm short channel MOSFET. In particular, the SOI substrate 110 comprises a silicon substrate 111, a buried oxide layer 112 on the silicon substrate 111, and a top silicon layer on the buried oxide layer 112, where the thickness of the top silicon layer 113 may be less than or equal to 10 nm. In the step of forming a basic structure, the source/drain implantation is not performed.

Second, a metal layer is deposited. As illustrated in FIG. 5, a metal thin layer 600/610 for forming metal silicide is deposited on the whole basic device structure, to cover the substrate, gate structure, and gate sidewall spacers. The material for the metal thin layer may be one of cobalt Co, nickel Ni, Ni—Pt (where the Pt content is less than or equal to 85) and Ni—Co (the Co content is less than or equal to 10%), etc. The thickness of the metal thin layer may be less than or equal to 5 nm, preferably less than or equal to 4 nm. Specifically, the metal thin layer may be a Co layer with a thickness less than or equal to 5 nm, or a Ni, Ni—Pt, or Ni—Co layer with a thickness less than 4 nm.

Next, a first annealing is performed. The first annealing is performed under a temperature between 500-850° C., so that epitaxially grown ultrath in metal silicide source/drain regions are formed.

Next, unreacted metal layer are striped off, to obtain epitaxially grown ultrathin metal silicide source/drain 700/710, as illustrated in FIG. 6. Depending on the material of the deposited metal thin layer 600/610, the material of the epitaxially grown ultrathin metal silicide source/drain 700/710 may be one of NiSi_{2-y}, Ni₁₋ₓPtₓSi_{2-y}, CoSi_{2-y} and Ni₁₋ₓCoxSi_{2-y}, wherein x is greater than 0 but less than 1, and y is greater than or equal to 0 but less than 1. The thickness of the epitaxially grown ultrathin metal silicide source/drain 700/710 is less than or equal to 15 nm. Because of the reasonably selected material and thickness of the metal thin layer and the control of the first annealing temperature, the epitaxially grown ultrathin silicide is inherent to have good thermal stability and can bear the late-stage high-temperature annealing process, in particular the temperature for the second annealing required to form dopant segregation regions.

Next, dopants are implanted into the epitaxially grown ultrathin silicide source/drain regions, as illustrated in FIG. 7. The dosage of the dopants that are implanted into the epitaxially grown ultrathin metal silicide source/drain 700/710 ranges from 1×10¹⁴ to 1×10¹⁶ cm⁻². For p-type MOSFETs with epitaxially grown ultrathin metal silicide source/drain, the dopants may be one or more of boron B, aluminum Al, gallium Ga, indium In, and etc. For n-type MOSFETs with epitaxially grown ultrathin metal silicide source/drain, the dopants may be one or more of nitrogen, phosphorus, arsenic, oxygen, sulphur, selenium, tellurium, fluorine, and chlorine. Since the implantation process will lead to damage in the epitaxially grown ultrathin metal silicide source/drain, so the implantation energy should not be too large. The implantation energy should be low enough so as to guarantee that most of the implanted dopants are confined within the epitaxially grown ultrathin silicide source/drain.

Finally, a second annealing is performed. The second annealing is performed within a temperature range of 500-850° C., where the dopants in the epitaxially grown ultrathin metal silicide source/drain 700/710 are driven to the silicide/silicon interfaces, so that dopant segregation regions 800/810 are formed.

The cross-sectional diagram of the structure of the finally formed semiconductor device is illustrated in FIG. 8, which comprises a bulk-silicon substrate 100 or SOI substrate 110 (SOI substrate 110 comprises a silicon substrate 111, a buried oxide layer 112 on the silicon substrate 111, and a top silicon layer 113 on the buried oxide layer 112, wherein the thickness of the top silicon layer 113 may be less than or equal to 10 nm), where a channel region 200/210 is in the substrate 100/110, the epitaxially grown ultrathin metal silicide source/drain regions 700/710 are on both sides of the channel region, a gate structure 300/310 is on the channel region, and gate sidewall spacers 400/410 are formed on both sidewalls of the gate structure; the substrate 100/110 may further have an STI 500/510, and dopant segregation regions 800/810 are formed at the interfaces between the epitaxially grown ultrathin metal silicide source/drain 700/710 and the channel region 200/210.

In a preferred embodiment, the material of the epitaxially grown ultrathin metal silicide is one of NiSi_{2-y}, Ni₁₋ₓPtₓSi_{2-y}, CoSi_{2-y} and Ni₁₋ₓCoₓSi_{2-y}, wherein x is greater than 0 but less than 1, and y is greater than or equal to 0 but less than 1, with the thickness less than or equal to 15 nm. For p-type MOSFETs with epitaxially grown ultrathin metal silicide source/drain, the dopants may be one or more of boron B, aluminum Al, gallium Ga, indium In, and etc.; for n-type MOSFETs with epitaxially grown ultrathin metal silicide source/drain, the dopants may be one or more of nitrogen, phosphorus, arsenic, oxygen, sulphur, selenium, tellurium fluorine, and chlorine.

This MOSFET with epitaxially grown ultrathin metal silicide source/drain characterized by dopant segregation regions has many advantages. First, replacing traditional highly doped source/drain with metal silicide source/drain may alleviate parasitic series resistance and contact resistance to a great extent, such that the short channel effects immunity can be greatly improved in the sub-20 nm CMOS technology nodes. Second, because the metal silicide precursor may be well controlled (namely, the thickness of the deposited metal layer and the processing parameters, particularly the time and the temperature range for the first annealing may be well controlled), the formed epitaxially grown ultrathin silicide source/drain are made to have a better thermal stability and subjected to the silicide as diffusion source technology to reduce the Schottky Barrier Height (SBH). Specifically, dopant segregation regions are formed at the interfaces between the epitaxially grown ultrathin silicide source/drain and the channel region, thereby reducing the SBH and enhancing the driving capability of the device. Moreover, the second annealing under a high temperature for lowering the SBH may repair the damage of the silicide film caused by ion implantation. In short, by employing the MOSFET and the method for manufacturing the same according to embodiments of the present invention, MOSFETs with stable epitaxially grown ultrathin metal silicide source/drain may be obtained in combination with the SADS method to improve the driving capability of the devices.

Although the present invention has been described with reference to one or more exemplary embodiments, those skilled in the art may know that various appropriate changes and equivalent manners may be made or adopted to the device without departing from the scope of the present invention. Besides, from the disclosed teaching, many modifications that may be appropriate to a particular circumstance or material may be made without departing from the scope of the present invention. Thus, the objective of the present invention is not limited to the specific embodiments that are disclosed to implement the preferred embodiments of the present invention, while the disclosed device structure and its manufacturing method will include all embodiments within the scope of the present invention.

What is claimed is:

1. A semiconductor device, comprising a substrate, a channel region in the substrate, source/drain regions on both sides of the channel region, a gate structure on the channel region, and gate sidewall spacers formed on both sidewalls of the gate structure, characterized in that:
each of the source/drain regions comprises epitaxially grown metal silicide, and a dopant segregation region is formed at the interface between each of the source/drain regions and the channel region.

2. The semiconductor device according to claim 1, characterized in that the material of the epitaxially grown ultrathin metal silicide source/drain regions is one of NiSi_{2-y}, Ni₁₋ₓPtₓSi_{2-y}, CoSi_{2-y} and Ni₁₋ₓCoₓSi_{2-y}, wherein x is greater than 0 but less than 1, and y is greater than or equal to 0 but less than 1.

3. The semiconductor device according to claim 1, characterized in that the thickness of the epitaxially grown metal silicide source/drain regions is less than or equal to 15 nm.

4. The semiconductor device according to claim 1, characterized in that for p-type MOSFETs with epitaxially grown ultrathin metal silicide source/drain, the dopants are one or more of boron B, aluminum Al, gallium Ga, indium In, and etc.; for n-type MOSFETs with epitaxially grown ultrathin metal silicide source/drain, the dopants are one or more of nitrogen N, phosphorus P, arsenic As, oxygen O, sulphur S, selenium Se, tellurium Te, fluorine F, and chlorine Cl.

5. The semiconductor device according to claim 1, characterized in that the substrate is a bulk-silicon substrate or a semiconductor-on-insulator substrate.

6. A method for manufacturing a semiconductor device, comprising:
forming a gate structure and gate sidewall spacers on the substrate;
depositing a metal layer that covers the substrate, the gate structure, and the gate sidewall spacers;
performing a first annealing such that the metal layer on both sides of the gate reacts with the substrate to form epitaxially grown metal silicide layers;
stripping un-reacted metal layer, such that the epitaxially grown metal silicide layers form source/drain regions of the device, and a portion of the semiconductor substrate beneath the gate structure forms the channel region;
implanting dopants into the epitaxially grown ultrathin silicide source/drain regions; and
performing a second annealing to form dopant segregation regions at the interfaces between the epitaxially grown ultrathin silicide source/drain regions and the channel region.

7. The method according to claim 6, wherein the material of the epitaxially grown ultrathin metal silicide is one of NiSi_{2-y}, Ni₁₋ₓPtₓSi_{2-y}, CoSi_{2-y} and Ni₁₋ₓCoₓSi_{2-y}, wherein x is greater than 0 but less than 1, and y is greater than or equal to 0 but less than 1.

8. The method according to claim 6, wherein for p-type MOSFETs with epitaxially grown ultrathin metal silicide source/drain, the dopants are one or more of boron B, aluminum Al, gallium Ga, indium In, and etc.; for n-type MOSFETs with epitaxially grown ultrathin metal silicide source/drain, the dopants are one or more of nitrogen N, phosphorus P, arsenic As, oxygen O, sulphur S, selenium Se, tellurium Te, fluorine F, and chlorine Cl.

9. The method according to claim 6, wherein the temperature for the first annealing and/or for the second annealing is in a range of 500-850° C.

10. The method according to claim 6, wherein the implantation dosage is in a range from 1×10¹⁴ to 1×10¹⁶ cm⁻².

11. The method according to claim 6, wherein the thickness of the metal layer is less than or equal to 5 nm.

12. The method according to claim 6, wherein the substrate is a bulk-silicon substrate or a semiconductor-on-insulator substrate.
